(19) United States
(12) Patent Application Publication
(10) Pub. No.: US 2024/0363810 A1
(43) Pub. Date: Oct. 31, 2024

(54) LIGHT-CONVERSION MATERIAL AND LIGHT-EMITTING DEVICE AND DISPLAY DEVICE INCLUDING THE SAME

(71) Applicant: Lextar Electronics Corporation, Hsinchu (TW)

(72) Inventors: Lu-Ching WANG, Hsinchu City (TW); Pei Cong YAN, Hsinchu City (TW); Hung-Chun TONG, Hsinchu City (TW); Yu-Chun LEE, Hsinchu City (TW)

(21) Appl. No.: 18/517,401

(22) Filed: Nov. 22, 2023

(30) Foreign Application Priority Data
Apr. 27, 2023 (TW) 112115731

(51) Int. Cl. H01L 33/50

(52) U.S. Cl. CPC H01L 33/502

(57) ABSTRACT

A light-conversion material and a light-emitting device and a display device including the same are provided. The light-conversion material is represented by formula (I): MₘD_{d}AₐC_{c}EₑG_{g}:Rᵣ (I). Wherein M is Ca, Sr, or Ba; D is Zn, Cd, or a combination thereof; A is B, Al, or Ga; C is Si; E is O, S, or Se; G is N, P, As, Sb, or Bi; and R is Eu, Sm, or Yb. The formula (I) is satisfied by 0.5≤m≤2; 1≤d≤4; 0≤a≤2; 0.1≤c≤3.5; 0.1≤e≤4; 0.5≤g≤5.5; and 0.1≤r≤1.

### CROSS REFERENCE TO RELATED APPLICATIONS

This application claims priority of Taiwan Patent Application No. 112115731, filed on Apr. 27, 2023, the entirety of which is incorporated by reference herein.

### Technical Field

The disclosure relates to a light-conversion material and a light-emitting device and a display device including the same, and, in particular, to a light-conversion material with narrow full width at half maximum (FWHM) and a light-emitting device and a display device including the same.

### BACKGROUND

### Description of the Related Art

Recently, light-emitting devices and display devices have undergone rapid development, and many products have gradually become high-tech and high-standard. However, there are still various limitations to the development of light-emitting devices and display devices. For example, due to the physical limitations of the materials used to make light-emitting diodes (LED), it is difficult to effectively improve the gamut coverage of the LEDs.

LEDs can be used with light-conversion materials to emit light with a specific color. However, the light-conversion materials commonly used in displays still have the problem of a wide light-emitting spectrum. Therefore, there is still a need in the art to seek light-conversion materials with a narrow full width at half maximum (FWHM) and light-emitting devices and display devices including the same.

### SUMMARY

The present disclosure provides a light-conversion material with narrow full width at half maximum (FWHM) and a light-emitting device and a display device including the same.

An embodiment of the disclosure provides a light-conversion material. The light-conversion material is represented by formula (I):

MₘD_{d}AₐC_{c}EₑG_{g}:Rᵣ (I),

wherein M is Ca, Sr, or Ba; D is Zn, Cd, or a combination thereof, A is B, Al, or Ga; C is Si; E is O, S, or Se; G is N, P, As, Sb, or Bi; and R is Eu, Sm, or Yb. The formula (I) is satisfied by 0.5≤m≤2; 1≤d≤4; 0≤a≤2; 0.1≤c≤3.5; 0.1≤e≤4; 0.5≤g≤5.5; and 0.1≤r≤1.

An embodiment of the disclosure provides a light-emitting device. The light-emitting device including a light source and a light-conversion material. The light source emits an excitation light, wherein the excitation light has an emission peak wavelength in a range above 400 nm and below 480 nm. The light-conversion material is described above. The light-conversion material absorbs a portion of the excitation light to emit a green light, the green light has an emission peak wavelength in a range above 480 nm and below 580 nm, and the green light has the maximum emission intensity. When the emission intensity is 50% of the maximum emission intensity, the difference between the maximum value and the minimum value of the emission wavelength of the light-conversion material is D₅₀. When the emission intensity is 10% of the maximum emission intensity, the difference between the maximum value and the minimum value of the emission wavelength of the light-conversion material is D₁₀, and 2.5 D₅₀≤D₁₀≤5.5 D₅₀.

In addition, an embodiment of the disclosure provides a display device. The display device includes the light-emitting device described above.

According to some embodiments of the present disclosure, the FWHM of the light-conversion material can be adjusted by adjusting the elements and proportions in the formula (I) of the light-conversion material to obtain a light-conversion material with a narrow FWHM. Furthermore, by adjusting the elements and proportions in the formula (I) of the light-conversion material, the wave width of the emission peak of the light-conversion material can be adjusted, thereby obtaining a light-conversion material with a narrow wave width.

### BRIEF DESCRIPTION OF THE DRAWINGS

Aspects of the disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates an emission spectrum of a wavelength versus an intensity for a light-conversion material according to some embodiments of the present disclosure.

FIG. 2 illustrates an emission spectrum of a wavelength versus an intensity for a light-conversion material according to some embodiments of the present disclosure.

FIG. 3 illustrates an emission spectrum of a wavelength versus an intensity for a light-conversion material according to some embodiments of the present disclosure.

FIG. 4 illustrates emission spectrums of a wavelength versus an intensity for light-conversion materials according to some embodiments of the present disclosure.

FIG. 5 illustrates a scanning electron microscope (SEM) image of light-conversion materials according to some embodiments of the present disclosure.

FIGS. 6A and 6B illustrate schematic diagrams of light-emitting devices according to some embodiments of the present disclosure.

FIGS. 7A and 7B illustrate schematic diagrams of light-emitting devices according to some embodiments of the present disclosure.

FIGS. 8A and 8B illustrate schematic diagrams of light-emitting devices according to some embodiments of the present disclosure.

FIG. 9A illustrates a schematic diagram of a light-emitting device according to some embodiments of the present disclosure.

FIG. 9B illustrates a schematic diagram of a light-emitting device according to some embodiments of the present disclosure.

FIG. 9C illustrates a schematic diagram of a light-emitting device according to some embodiments of the present disclosure.

FIG. 10 illustrates a schematic diagram of a display device according to some embodiments of the present disclosure.

### DETAILED DESCRIPTION

The following disclosure provides many different embodiments, or examples, for implementing different features of the provided subject matter. Specific examples of components and arrangements are described below to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It should be understood that additional operations can be provided before, during, and/or after the stages described in these embodiments. Some of the stages that are described can be replaced or eliminated for different embodiments.

Furthermore, spatially relative terms, such as “beneath,” “below,” “lower,” “above,” “upper”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Here, the terms “about”, “approximately”, “substantially” usually means within 20%, within 10%, within 5%, within 3%, within 2%, within 1% or within 0.5% of a given value or range. Here, the given value is an approximate number. That is, in the absence of a specific description of “about”, “approximately”, “substantially”, the meaning of “about”, “approximately”, “substantially” may still be implied. Besides, the expression “A-B” or “A to B” indicates the range includes values greater than or equal to A and values less than or equal to B. In the specification, the expression “above A” indicates the range includes values greater than or equal to A, the expression “below A” indicates the range includes values less than or equal to A.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

Different embodiments disclosed below may reuse the same reference symbols and/or labels. These repetitions are for the purpose of simplicity and clarity and are not intended to limit the specific relationship between the various embodiments and/or structures discussed below.

Hereinafter, the term “full width at half maximum (FWHM)” refers to the distance between two points whose function value is equal to half of the peak value in a peak of a function. In an optical field, FWHM refers to a wave width at half the peak height. For example, in a function of the emission wavelength (unit: nanometer (nm)) on the x-axis and the emission intensity (arbitrary unit (a.u.)) on the y-axis, FWHM is the difference between the maximum and minimum values of the emission wavelength at an emission intensity of 50% of the maximum emission intensity. In other words, the definitions of FWHM and D₅₀ herein may be the same. In addition, it is also defined herein that the difference between the maximum and the minimum values of the emission wavelength at an emission intensity of 10% of the maximum emission intensity is D₁₀.

Hereinafter, the term “substantially does not include” means that it is not substantially added or it is not detected by the testing instrument.

Hereinafter, the term “mini light-emitting diode (also called mini-LED, sub-millimeter light-emitting diode)” can refer to a light-emitting diode with a size between a traditional LED and a micro LED.

In some embodiments, a light-conversion material is provided. The light-conversion material is represented by formula (I):

MₘD_{c}AₐC_{c}EₑG_{g}:Rᵣ (I),

wherein M, D, A, C, E, G, and R individually represent elements (or combinations of elements), and m, d, a, c, e, g, and r represent proportions (or ratios) of elements.

In some embodiments, M may include group IIA elements. For example, M may be calcium (Ca), strontium (Sr), or barium (Ba). In some embodiments, m satisfies 0.5≤m≤2. For example, m may be 0.5, 0.6, 0.7, 0.8, 0.9, 1, 1.1, 1.2, 1.3, 1.4, 1.5, 1.6, 1.8, 2, or other values, but the present disclosure is not limited thereto.

In some embodiments, D may include group IIB elements. For example, D may be zinc (Zn), cadmium (Cd), or a combination thereof. In some embodiments, d satisfies 1≤d≤4. For example, d may be 1, 1.2, 1.6, 1.8, 2, 2.2, 2.4, 2.7, 3, 3.5, 4, or other values, but the present disclosure is not limited thereto.

In some embodiments, A may include group IIIA elements. For example, A may be boron (B), aluminum (Al), or gallium (Ga). In some embodiments, a satisfies 0≤a≤2. For example, a may be 0, 0.1, 0.2, 0.3, 0.4, 0.5, 0.6, 0.7, 0.8, 0.9, 1, 1.2, 1.5, 1.7, 2, or other values, but the present disclosure is not limited thereto. In some embodiments, when a is 0, it means that the light-conversion material substantially does not include a.

In some embodiments, C may include group IVA elements. For example, C may be Si. In some embodiments, c satisfies 0.1≤c≤3.5. For example, c may be 0.1, 0.2, 0.4, 0.6, 0.8, 1, 1.2, 1.4, 1.6, 1.8, 2, 2.5, 2.8, 3, 3.5, or other values, but the present disclosure is not limited thereto.

In some embodiments, E may include group VIA elements. For example, E may be oxygen (O), sulfur (S), or selenium (Se). In some embodiments, e satisfies 0.1≤e≤4. For example, e may be 0.1, 0.2, 0.3, 0.4, 0.6, 0.8, 1, 1.5, 2, 3, 3.5, 3.6, 3.7, 3.8, 3.9, 4, or other values, but the present disclosure is not limited thereto.

In some embodiments, G may include Group VA elements. For example, G may be nitrogen (N), phosphorus (P), arsenic (As), antimony (Sb), or bismuth (Bi). In some embodiments, g satisfies 0.5≤g≤5.5. For example, g may be 0.5, 0.7, 0.9, 1, 1.3, 1.5, 1.7, 2, 2.3, 2.4, 2.5, 3, 3.5, 3.7, 3.9, 4, 4.1, 4.5, 4.7, 5, 5.1, 5.3, 5.5, or other values, but the present disclosure is not limited thereto.

In some embodiments, R may include lanthanide elements. For example, R may be europium (Eu), samarium (Sm), or ytterbium (Yb). In some embodiments, r satisfies 0.1≤r≤1. For example, r may be 0.1, 0.2, 0.3, 0.4, 0.5, 0.6, 0.7, 0.8, 0.9, 1, or other values, but the present disclosure is not limited thereto.

In some embodiments, M may be +2 valence, D may be +2 valence, A may be +3 valence, C may be +4 valence, E may be −2 valence, G may be −3 valence, and R may be +2 valence, so the valences of M, D, A, C, R are positive, while the valences of E and G are negative. The valence balance of the light-conversion material can be adjusted by adjusting the values of e and g.

In some embodiments, the light-conversion material of the present disclosure can absorb a light in the wavelength range above 400 nm and below 480 nm to emit a green light. In some embodiments, the light may be an excitation light emitted from a light source. For example, the excitation light may be an ultraviolet light or a blue light. In other words, the light-conversion material of the present disclosure may be excited by the light with the wavelength range above 400 nm and below 480 nm to emit green light. In some embodiments, the green light emitted by the light-conversion material has an emission peak wavelength in a range above 480 nm and below 580 nm. In some embodiments, the green light emitted by the light-conversion material has an emission peak wavelength in a range above 525 nm and below 540 nm. In some embodiments, the green light emitted by the light-conversion material may have a maximum emission intensity. When the emission intensity is 50% of the maximum emission intensity, the difference between the maximum value and the minimum value of the emission wavelength of the light-conversion material is D₅₀. When the emission intensity is 10% of the maximum emission intensity, the difference between the maximum value and the minimum value of the emission wavelength of the light-conversion material is D₁₀. In some embodiments, the light-conversion material satisfies 2.5D₅₀≤D₁₀≤5.5D₅₀. In some embodiments, if the D₁₀ is less than 2.5D₅₀, the brightness of the light-conversion material may be insufficient, and if the D₁₀ is greater than 5.5D₅₀, the wave width of the emission spectrum can be too large that may reduce the color accuracy.

In some embodiments, the light-conversion material can be represented by any of the following formula (I):

Sr_{0.5}Cd_{2.4}Al_{1.5}Si_{1.6}O_{3.6}N_{3.5}:Eu_{0.5};Sr_{1.4}Cd_{2.4}Al_{1.5}Si_{1.6}O_{3.6}N_{4.1}:Eu_{0.5};Sr₂Cd_{2.4}Al_{1.5}Si_{1.6}O_{3.6}N_{4.5}:Eu_{0.5};Sr_{0.5}Cd_{2.7}Al_{1.5}Si_{1.6}O_{3.6}N_{3.7}:Eu_{0.5};Sr_{0.5}Cd₃Al_{1.5}Si_{1.6}O_{3.6}N_{3.9}:Eu_{0.5};Sr_{0.5}Cd₄Al_{1.5}Si_{0.1}O_{3.7}N_{2.5}:Eu_{0.5};Sr_{0.5}Cd_{2.4}Si_{1.6}O_{3.6}N₂:Eu_{0.5};Sr_{0.5}Cd_{2.4}Al₁Si_{1.6}O_{3.6}N₃:Eu_{0.5};Sr_{0.5}Cd_{2.4}Al₂Si_{1.6}O_{3.6}N₄:Eu_{0.5};Sr_{0.5}Cd_{2.4}Al_{1.5}Si_{1.6}O_{3.6}N₄:Eu_{0.5};Sr_{0.5}Cd_{2.4}Al_{1.5}Si_{2.5}O_{3.6}N_{4.7}:Eu_{0.5};Sr_{0.5}Cd_{2.4}Al_{1.5}Si_{2.5}O_{3.6}N_{5.1}:Eu_{0.5};Sr_{0.5}Cd_{2.4}Al_{1.5}Si_{0.1}N_{3.9}:Eu_{0.5};Sr_{0.5}Cd_{2.4}Al_{1.5}Si_{0.1}O_{0.3}N_{3.7}:Eu_{0.5};Sr_{0.5}Cd_{2.4}Al_{1.5}Si_{0.1}O_{3.9}N_{1.3}:Eu_{0.5};Ca_{0.5}Cd_{2.4}Al_{1.5}Si_{1.6}O_{3.6}N_{3.5}:Eu_{0.5};Ba_{0.5}Cd_{2.4}Al_{1.5}Si_{1.6}O_{3.6}N_{3.5}:Eu_{0.5};Sr_{0.5}Zn_{2.4}Al_{1.5}Si_{1.6}O_{3.6}N_{3.5}:Eu_{0.5};Sr_{0.5}Cd_{2.4}B₁Si_{1.6}O_{3.6}N₃:Eu_{0.5};Sr_{0.5}Cd_{2.4}Ga₁Si_{1.6}O_{3.6}N₃:Eu_{0.5};Sr_{0.5}Cd_{2.4}Al_{1.5}Si_{1.6}S_{3.6}N_{3.5}:Eu_{0.5};Sr_{0.5}Cd_{2.4}Al_{1.5}Si_{1.6}O_{3.6}N_{3.5}:Eu_{0.5};Sr_{0.5}Cd_{2.4}Al_{1.5}Si_{0.1}O_{0.3}P_{3.7}:Eu_{0.5};Sr_{0.5}Cd_{2.4}Al_{1.5}Si_{0.1}O_{0.3}As_{3.7}:Eu_{0.5};Sr_{0.5}Cd_{2.4}Al_{1.5}Si_{0.1}O_{0.3}Sb_{3.7}:Eu_{0.5};Sr_{0.5}Cd_{2.4}Al_{1.5}Si_{0.1}O_{0.3}Bi_{3.7}:Eu_{0.5};Sr_{0.5}Cd_{2.4}Al_{1.5}Si_{1.6}O_{3.6}N_{3.5}Sm_{0.5};Sr_{0.5}Cd_{2.4}Al_{1.5}Si_{1.6}O_{3.6}N_{3.5}:Yb_{0.5};Ca_{0.5}Cd_{2.4}Si_{1.6}O_{3.6}N₂:Eu_{0.5};Ba_{0.5}Cd_{2.4}Si_{1.6}O_{3.6}N₂:Eu_{0.5};Sr_{0.5}Zn_{2.4}Si_{1.6}O_{3.6}N₂:Eu_{0.5};Sr_{0.5}Cd_{2.4}Si_{1.6}S_{3.6}N₂:Eu_{0.5};Sr_{0.5}Cd_{2.4}Si_{1.6}Se_{3.6}N₂:Eu_{0.5};Sr_{0.5}Cd_{2.4}Si_{1.6}O_{3.6}P₂:Eu_{0.5};Sr_{0.5}Cd_{2.4}Si_{1.6}O_{3.6}As₂:Eu_{0.5};Sr_{0.5}Cd_{2.4}Si_{1.6}O_{3.6}Sb₂:Eu_{0.5};Sr_{0.5}Cd_{2.4}Si_{1.6}O_{3.6}Bi₂:Eu_{0.5};Sr_{0.5}Cd_{2.4}Si_{1.6}O_{3.6}N₂:Sm_{0.5};Sr_{0.5}Cd_{2.4}Si_{1.6}O_{3.6}N₂:Yb_{0.5};Sr_{1.1}Cd_{1.2}Al_{0.5}Si_{0.6}O₁N_{2.5}:Eu_{0.5};Sr_{0.5}Cd_{1.2}Al_{0.5}Si_{0.6}O_{0.4}N_{2.5}:Eu_{0.5};Sr_{1.1}Cd₁Al_{0.5}Si_{1.6}O_{0.8}N_{2.5}:Eu_{0.5};Sr_{1.1}Cd_{1.2}Si_{0.6}O_{0.4}N_{2.4}:Eu_{0.5};Sr_{1.1}Cd_{1.2}Al_{0.5}Si_{0.6}O_{0.6}N_{2.5}:Eu_{0.1};Sr_{0.5}Cd₄Al_{0.5}Si_{0.1}O_{0.1}N_{3.9}:Eu_{0.5};Sr₂Cd_{2.7}Al_{0.6}Si_{0.1}O_{0.1}N₄:Eu_{0.3};Sr_{1.1}Cd₁Al_{0.5}Si_{0.1}O_{0.1}N_{2.3}:Eu_{0.5};Sr_{0.5}Cd₁Si₃O₂N₄:Eu_{0.5};Ca_{1.1}Cd_{1.2}Al_{0.5}Si_{0.6}O₁N_{2.5}:Eu_{0.5};Ba_{1.1}Cd_{1.2}Al_{0.5}Si_{0.6}O₁N_{2.5}:Eu_{0.5};Sr_{1.1}Zn_{1.2}Al_{0.5}Si_{0.6}O₁N_{2.5}:Eu_{0.5};Sr_{1.1}Cd_{1.2}B_{0.5}Si_{0.6}O₁N_{2.5}:Eu_{0.5};Sr_{1.1}Cd_{1.2}Ga_{0.5}Si_{0.6}O₁N_{2.5}:Eu_{0.5};Sr_{1.1}Cd_{1.2}Al_{0.5}Si_{0.6}S₁N_{2.5}:Eu_{0.5};Sr_{1.1}Cd_{1.2}Al_{1.5}Si_{0.6}Se₁N_{2.5}:Eu_{0.5};Sr_{1.1}Cd_{1.2}Al_{0.5}Si_{0.6}O₁P_{2.5}:Eu_{0.5};Sr_{1.1}Cd_{1.2}Al_{1.5}Si_{0.6}O₁As_{2.5}:Eu_{0.5};Sr_{1.1}Cd_{1.2}Al_{0.5}Si_{0.6}O₁Sb_{2.5}:Eu_{0.5};Sr_{1.1}Cd_{1.2}Al_{1.5}Si_{0.6}O₁Bi₂:Eu_{0.5};Sr_{1.1}Cd_{1.2}Al_{0.5}Si_{0.6}O₁N_{2.5}:Sm_{0.5};Sr_{1.1}Cd_{1.2}Al_{1.5}Si_{0.6}O₁N_{2.5}:Yb_{0.5};Ca_{1.1}Cd_{1.2}Si_{0.6}O_{0.4}N_{2.4}:Eu_{0.5};Ba_{1.1}Cd_{1.2}Si_{0.6}O_{0.4}N_{2.4}:Eu_{0.5};Sr_{1.1}Zn_{1.2}Si_{0.6}O_{0.4}N_{2.4}:Eu_{0.5};Sr_{1.1}Cd_{1.2}Si_{0.6}O_{0.4}P_{2.4}:Eu_{0.5};Sr_{1.1}Cd_{1.2}Si_{0.6}O_{0.4}As_{2.4}:Eu_{0.5};Sr_{1.1}Cd_{1.2}Si_{0.6}O_{0.4}Sb_{2.4}:Eu_{0.5};Sr_{1.1}Cd_{1.2}Si_{0.6}O_{0.4}Bi_{2.4}:Eu_{0.5};Sr_{1.1}Cd_{1.2}Si_{0.6}O_{0.4}N_{2.4}:Sm_{0.5}; and Sr_{1.1}Cd_{1.2}Si_{0.6}O_{0.4}N_{2.4}:Yb_{0.5}.

In some embodiments, the light-conversion material of the present disclosure may be formed by the following steps (1) to (5).

### [Step (1)]

According to the formula (1) of the light-conversion material, the material including M, D, A, C, E, and G in the formula (1) is prepared as the first mixture. Wherein, M is Ca, Sr, or Ba. D is Zn, Cd or a combination thereof. A is B, Al, or Ga. C is Si. E is O, S, or Se. G is N, P, As, Sb, or Bi. In some embodiments, the materials including M, D, A, C, E, and G in formula (1) may include oxides, sulfides, carbonates, salts, and the like.

In some embodiments, the M material (materials including M in the formula (1)) includes M-containing oxides and/or M-containing carbonates, such as BaO, BaCO₃, SrCO₃, CaO, and/or CaCO₃, but the present disclosure is not limited thereto. In some embodiments, the D material (materials including D in the formula (1)) includes D-containing oxides and/or D-containing sulfides, such as ZnO, ZnS, and/or CdO, but the present disclosure is not limited thereto. In some embodiments, the A material (materials including A in the formula (1)) includes A-containing hydrides and/or A-containing oxides, such as NaBH₄, Al₂O₃, and/or Ga₂O₃, but the present disclosure is not limited thereto. In some embodiments, the C material (materials including C in the formula (1)) includes C-containing oxides, such as SiO₂, but the present disclosure is not limited thereto. In some embodiments, the E material (materials including E in the formula (1)) is E and/or includes E-containing oxides, such as S and/or SeO₂, but the present disclosure is not limited thereto. In some embodiments, G material (materials including G in the formula (1)) includes G-containing nitrates, G-containing phosphates, G-containing arsenates, G-containing antimonates, and/or G-containing bismuthates, but the present disclosure is not limited thereto. In some embodiments, the first mixture may further include a fusing agent. For example, the fusing agent may be NaF or Na₂CO₃.

### [Step (2)]

A sintering process is performed on the first mixture to obtain a first product. In some embodiments, the temperature of the sintering process is between 200° C. and 600° C. For example, the temperature of the sintering process may be 200° C., 300° C., 400° C., 500° C., 600° C., or other values, but the present disclosure is not limited thereto. In some embodiments, seed crystals are formed in the first mixture before performing the sintering process.

### [Step (3)]

According to the formula (1) of the light-conversion material, the material of the element R and the first product are prepared as a second mixture. In some embodiments, the material of the element R includes R-containing oxides, such as Eu₂O₃, Yb₂O₃, and/or Sm₂O₃, but the present disclosure is not limited thereto.

### [Step (4)]

A calcination process is performed on the second mixture in a reducing gas environment to obtain a second product. In some embodiments, the temperature of the calcination process is between 800° C. and 1400° C. For example, the temperature of the calcination process may be 800° C., 900° C., 1000° C., 1100° C., 1200° C., 1300° C., 1400° C., or other values, but the present disclosure is not limited thereto. In some embodiments, the reducing gas may include hydrogen.

### [Step (5)]

The second product is washed and dried to obtain the light-conversion material. In some embodiments, the second product may be washed with a solvent to remove unreacted reactants. For example, the solvent may be alcohols such as ethanol (EtOH), alkanes such as hexane, but the present disclosure is not limited thereto.

Hereinafter, Example (Ex.) 1 to Example (Ex.) 70 of the light-conversion material disclosed in the present disclosure are listed in Table 1, and the experimental results of Example to Example 70 are further shown in Table 1.

TABLE 1

| | | | | | | | | | | | | | | | peak | | | | | | |
|---|---|---|---|---|---|---|---|---|---|---|---|---|---|---|---|---|---|---|---|---|---|
| | | | | | | | | | | | | | | | value | FWHM | | | | | |
| Ex. | M | m | D | d | A | a | C | c | E | e | G | g | R | r | (nm) | (nm) | c/d | e/d | d/r | c/r | c/m |
| 1 | Sr | 0.5 | Cd | 2.4 | Al | 1.5 | Si | 1.6 | O | 3.6 | N | 3.5 | Eu | 0.5 | 531 | 25 | 0.67 | 1.50 | 4.80 | 3.20 | 3.20 |
| 2 | Sr | 1.4 | Cd | 2.4 | Al | 1.5 | Si | 1.6 | O | 3.6 | N | 4.1 | Eu | 0.5 | 534 | 25 | 0.67 | 1.50 | 4.80 | 3.20 | 1.14 |
| 3 | Sr | 2 | Cd | 2.4 | Al | 1.5 | Si | 1.6 | O | 3.6 | N | 4.5 | Eu | 0.5 | 540 | 25 | 0.67 | 1.50 | 4.80 | 3.20 | 0.80 |
| 4 | Sr | 0.5 | Cd | 2.7 | Al | 1.5 | Si | 1.6 | O | 3.6 | N | 3.7 | Eu | 0.5 | 531 | 24 | 0.59 | 1.33 | 5.40 | 3.20 | 3.20 |
| 5 | Sr | 0.5 | Cd | 3 | Al | 1.5 | Si | 1.6 | O | 3.6 | N | 3.9 | Eu | 0.5 | 531 | 23 | 0.53 | 1.20 | 6.00 | 3.20 | 3.20 |
| 6 | Sr | 0.5 | Cd | 4 | Al | 1.5 | Si | 0.1 | O | 3.7 | N | 2.5 | Eu | 0.5 | 531 | 21 | 0.03 | 0.93 | 8.00 | 0.20 | 0.20 |
| 7 | Sr | 0.5 | Cd | 2.4 | — | — | Si | 1.6 | O | 3.6 | N | 2 | Eu | 0.5 | 527 | 25 | 0.67 | 1.50 | 4.80 | 3.20 | 3.20 |
| 8 | Sr | 0.5 | Cd | 2.4 | Al | 1 | Si | 1.6 | O | 3.6 | N | 3 | Eu | 0.5 | 528 | 25 | 0.67 | 1.50 | 4.80 | 3.20 | 3.20 |
| 9 | Sr | 0.5 | Cd | 2.4 | Al | 2 | Si | 1.6 | O | 3.6 | N | 4 | Eu | 0.5 | 537 | 25 | 0.67 | 1.50 | 4.80 | 3.20 | 3.20 |
| 10 | Sr | 0.5 | Cd | 2.4 | Al | 1.5 | Si | 0.1 | O | 3.6 | N | 1.5 | Eu | 0.5 | 531 | 23 | 0.04 | 1.50 | 4.80 | 0.20 | 0.20 |
| 11 | Sr | 0.5 | Cd | 2.4 | Al | 1.5 | Si | 2.5 | O | 3.6 | N | 4.7 | Eu | 0.5 | 531 | 31 | 1.04 | 1.50 | 4.80 | 5.00 | 5.00 |
| 12 | Sr | 0.5 | Cd | 2.4 | Al | 1.5 | Si | 2.8 | O | 3.6 | N | 5.1 | Eu | 0.5 | 531 | 33 | 1.17 | 1.50 | 4.80 | 5.60 | 5.60 |
| 13 | Sr | 0.5 | Cd | 2.4 | Al | 1.5 | Si | 0.1 | — | — | N | 3.9 | Eu | 0.5 | 528 | 23 | 0.04 | 0.00 | 4.80 | 0.20 | 0.20 |
| 14 | Sr | 0.5 | Cd | 2.4 | Al | 1.5 | Si | 0.1 | O | 0.3 | N | 3.7 | Eu | 0.5 | 529 | 23 | 0.04 | 0.13 | 4.80 | 0.20 | 0.20 |
| 15 | Sr | 0.5 | Cd | 2.4 | Al | 1.5 | Si | 0.1 | O | 3.9 | N | 1.3 | Eu | 0.5 | 534 | 23 | 0.04 | 1.63 | 4.80 | 0.20 | 0.20 |
| 16 | Ca | 0.5 | Cd | 2.4 | Al | 1.5 | Si | 1.6 | O | 3.6 | N | 3.5 | Eu | 0.5 | 532 | 25 | 0.67 | 1.50 | 4.80 | 3.20 | 3.20 |
| 17 | Ba | 0.5 | Cd | 2.4 | Al | 1.5 | Si | 1.6 | O | 3.6 | N | 3.5 | Eu | 0.5 | 533 | 25 | 0.67 | 1.50 | 4.80 | 3.20 | 3.20 |
| 18 | Sr | 0.5 | Zn | 2.4 | Al | 1.5 | Si | 1.6 | O | 3.6 | N | 3.5 | Eu | 0.5 | 531 | 25 | 0.67 | 1.50 | 4.80 | 3.20 | 3.20 |
| 19 | Sr | 0.5 | Cd | 2.4 | B | 1 | Si | 1.6 | O | 3.6 | N | 3 | Eu | 0.5 | 528 | 25 | 0.67 | 1.50 | 4.80 | 3.20 | 3.20 |
| 20 | Sr | 0.5 | Cd | 2.4 | Ga | 1 | Si | 1.6 | O | 3.6 | N | 3 | Eu | 0.5 | 528 | 25 | 0.67 | 1.50 | 4.80 | 3.20 | 3.20 |
| 21 | Sr | 0.5 | Cd | 2.4 | Al | 1.5 | Si | 1.6 | S | 3.6 | N | 3.5 | Eu | 0.5 | 531 | 25 | 0.67 | 1.50 | 4.80 | 3.20 | 3.20 |
| 22 | Sr | 0.5 | Cd | 2.4 | Al | 1.5 | Si | 1.6 | Se | 3.6 | N | 3.5 | Eu | 0.5 | 531 | 25 | 0.67 | 1.50 | 4.80 | 3.20 | 3.20 |
| 23 | Sr | 0.5 | Cd | 2.4 | Al | 1.5 | Si | 0.1 | O | 0.3 | P | 3.7 | Eu | 0.5 | 529 | 23 | 0.04 | 0.13 | 4.80 | 0.20 | 0.20 |
| 24 | Sr | 0.5 | Cd | 2.4 | Al | 1.5 | Si | 0.1 | O | 0.3 | As | 3.7 | Eu | 0.5 | 529 | 23 | 0.04 | 0.13 | 4.80 | 0.20 | 0.20 |
| 25 | Sr | 0.5 | Cd | 2.4 | Al | 1.5 | Si | 0.1 | O | 0.3 | Sb | 3.7 | Eu | 0.5 | 529 | 23 | 0.04 | 0.13 | 4.80 | 0.20 | 0.20 |
| 26 | Sr | 0.5 | Cd | 2.4 | Al | 1.5 | Si | 0.1 | O | 0.3 | Bi | 3.7 | Eu | 0.5 | 529 | 23 | 0.04 | 0.13 | 4.80 | 0.20 | 0.20 |
| 27 | Sr | 0.5 | Cd | 2.4 | Al | 1.5 | Si | 1.6 | O | 3.6 | N | 3.5 | Sm | 0.5 | 531 | 25 | 0.67 | 1.50 | 4.80 | 3.20 | 3.20 |
| 28 | Sr | 0.5 | Cd | 2.4 | Al | 1.5 | Si | 1.6 | O | 3.6 | N | 3.5 | Yb | 0.5 | 531 | 25 | 0.67 | 1.50 | 4.80 | 3.20 | 3.20 |
| 29 | Ca | 0.5 | Cd | 2.4 | — | — | Si | 1.6 | O | 3.6 | N | 2 | Eu | 0.5 | 528 | 25 | 0.67 | 1.50 | 4.80 | 3.20 | 3.20 |
| 30 | Ba | 0.5 | Cd | 2.4 | — | — | Si | 1.6 | O | 3.6 | N | 2 | Eu | 0.5 | 529 | 25 | 0.67 | 1.50 | 4.80 | 3.20 | 3.20 |
| 31 | Sr | 0.5 | Zn | 2.4 | — | — | Si | 1.6 | O | 3.6 | N | 2 | Eu | 0.5 | 527 | 25 | 0.67 | 1.50 | 4.80 | 3.20 | 3.20 |
| 32 | Sr | 0.5 | Cd | 2.4 | — | — | Si | 1.6 | S | 3.6 | N | 2 | Eu | 0.5 | 527 | 25 | 0.67 | 1.50 | 4.80 | 3.20 | 3.20 |
| 33 | Sr | 0.5 | Cd | 2.4 | — | — | Si | 1.6 | Se | 3.6 | N | 2 | Eu | 0.5 | 527 | 25 | 0.67 | 1.50 | 4.80 | 3.20 | 3.20 |
| 34 | Sr | 0.5 | Cd | 2.4 | — | — | Si | 1.6 | O | 3.6 | P | 2 | Eu | 0.5 | 527 | 25 | 0.67 | 1.50 | 4.80 | 3.20 | 3.20 |
| 35 | Sr | 0.5 | Cd | 2.4 | — | — | Si | 1.6 | O | 3.6 | As | 2 | Eu | 0.5 | 527 | 25 | 0.67 | 1.50 | 4.80 | 3.20 | 3.20 |
| 36 | Sr | 0.5 | Cd | 2.4 | — | — | Si | 1.6 | O | 3.6 | Sb | 2 | Eu | 0.5 | 527 | 25 | 0.67 | 1.50 | 4.80 | 3.20 | 3.20 |
| 37 | Sr | 0.5 | Cd | 2.4 | — | — | Si | 1.6 | O | 3.6 | Bi | 2 | Eu | 0.5 | 527 | 25 | 0.67 | 1.50 | 4.80 | 3.20 | 3.20 |
| 38 | Sr | 0.5 | Cd | 2.4 | — | — | Si | 1.6 | O | 3.6 | N | 2 | Sm | 0.5 | 527 | 25 | 0.67 | 1.50 | 4.80 | 3.20 | 3.20 |
| 39 | Sr | 0.5 | Cd | 2.4 | — | — | Si | 1.6 | O | 3.6 | N | 2 | Yb | 0.5 | 527 | 25 | 0.67 | 1.50 | 4.80 | 3.20 | 3.20 |
| 40 | Sr | 1.1 | Cd | 1.2 | Al | 0.5 | Si | 0.6 | O | 1 | N | 2.5 | Eu | 0.5 | 534 | 26 | 0.50 | 0.83 | 2.40 | 1.20 | 0.55 |
| 41 | Sr | 0.5 | Cd | 1.2 | Al | 0.5 | Si | 0.6 | O | 0.4 | N | 2.5 | Eu | 0.5 | 539 | 24 | 0.50 | 0.33 | 2.40 | 1.20 | 1.20 |
| 42 | Sr | 1.1 | Cd | 1 | Al | 0.5 | Si | 0.6 | O | 0.8 | N | 2.5 | Eu | 0.5 | 534 | 25 | 0.60 | 0.80 | 2.00 | 1.20 | 0.55 |
| 43 | Sr | 1.1 | Cd | 1.2 | — | — | Si | 0.6 | O | 0.4 | N | 2.4 | Eu | 0.5 | 529 | 23 | 0.50 | 0.33 | 2.40 | 1.20 | 0.55 |
| 44 | Sr | 1.1 | Cd | 1.2 | Al | 0.5 | Si | 0.6 | O | 0.6 | N | 2.5 | Eu | 0.1 | 531 | 24 | 0.50 | 0.50 | 12.00 | 6.00 | 0.55 |
| 45 | Sr | 0.5 | Cd | 4 | Al | 0.5 | Si | 0.1 | O | 0.1 | N | 3.9 | Eu | 0.5 | 539 | 22 | 0.03 | 0.03 | 8.00 | 0.20 | 0.20 |
| 46 | Sr | 2 | Cd | 2.7 | Al | 0.6 | Si | 0.1 | O | 0.1 | N | 4 | Eu | 0.3 | 540 | 25 | 0.04 | 0.04 | 9.00 | 0.33 | 0.05 |
| 47 | Sr | 1.1 | Cd | 1 | Al | 0.5 | Si | 0.1 | O | 0.1 | N | 2.3 | Eu | 0.5 | 531 | 24 | 0.10 | 0.10 | 2.00 | 0.20 | 0.09 |
| 48 | Sr | 0.5 | Cd | 1 | — | — | Si | 3 | O | 2 | N | 4 | Eu | 0.5 | 527 | 43 | 3.00 | 2.00 | 2.00 | 6.00 | 6.00 |
| 49 | Ca | 1.1 | Cd | 1.2 | Al | 0.5 | Si | 0.6 | O | 1 | N | 2.5 | Eu | 0.5 | 535 | 27 | 0.50 | 0.83 | 2.40 | 1.20 | 0.55 |
| 50 | Ba | 1.1 | Cd | 1.2 | Al | 0.5 | Si | 0.6 | O | 1 | N | 2.5 | Eu | 0.5 | 534 | 25 | 0.50 | 0.83 | 2.40 | 1.20 | 0.55 |
| 51 | Sr | 1.1 | Zn | 1.2 | Al | 0.5 | Si | 0.6 | O | 1 | N | 2.5 | Eu | 0.5 | 534 | 27 | 0.50 | 0.83 | 2.40 | 1.20 | 0.55 |
| 52 | Sr | 1.1 | Cd | 1.2 | B | 0.5 | Si | 0.6 | O | 1 | N | 2.5 | Eu | 0.5 | 536 | 26 | 0.50 | 0.83 | 2.40 | 1.20 | 0.55 |
| 53 | Sr | 1.1 | Cd | 1.2 | Ga | 0.5 | Si | 0.6 | O | 1 | N | 2.5 | Eu | 0.5 | 534 | 27 | 0.50 | 0.83 | 2.40 | 1.20 | 0.55 |
| 54 | Sr | 1.1 | Cd | 1.2 | Al | 0.5 | Si | 0.6 | S | 1 | N | 2.5 | Eu | 0.5 | 534 | 27 | 0.50 | 0.83 | 2.40 | 1.20 | 0.55 |
| 55 | Sr | 1.1 | Cd | 1.2 | Al | 0.5 | Si | 0.6 | Se | 1 | N | 2.5 | Eu | 0.5 | 535 | 25 | 0.50 | 0.83 | 2.40 | 1.20 | 0.55 |
| 56 | Sr | 1.1 | Cd | 1.2 | Al | 0.5 | Si | 0.6 | O | 1 | P | 2.5 | Eu | 0.5 | 535 | 27 | 0.50 | 0.83 | 2.40 | 1.20 | 0.55 |
| 57 | Sr | 1.1 | Cd | 1.2 | Al | 0.5 | Si | 0.6 | O | 1 | As | 2.5 | Eu | 0.5 | 537 | 26 | 0.50 | 0.83 | 2.40 | 1.20 | 0.55 |
| 58 | Sr | 1.1 | Cd | 1.2 | Al | 0.5 | Si | 0.6 | O | 1 | Sb | 2.5 | Eu | 0.5 | 534 | 26 | 0.50 | 0.83 | 2.40 | 1.20 | 0.55 |
| 59 | Sr | 1.1 | Cd | 1.2 | Al | 0.5 | Si | 0.6 | O | 1 | Bi | 2.5 | Eu | 0.5 | 537 | 25 | 0.50 | 0.83 | 2.40 | 1.20 | 0.55 |
| 60 | Sr | 1.1 | Cd | 1.2 | Al | 0.5 | Si | 0.6 | O | 1 | N | 2.5 | Sm | 0.5 | 535 | 26 | 0.50 | 0.83 | 2.40 | 1.20 | 0.55 |
| 61 | Sr | 1.1 | Cd | 1.2 | Al | 0.5 | Si | 0.6 | O | 1 | N | 2.5 | Yb | 0.5 | 536 | 25 | 0.50 | 0.83 | 2.40 | 1.20 | 0.55 |
| 62 | Ca | 1.1 | Cd | 1.2 | — | — | Si | 0.6 | O | 0.4 | N | 2.4 | Eu | 0.5 | 529 | 23 | 0.50 | 0.33 | 2.40 | 1.20 | 0.55 |
| 63 | Ba | 1.1 | Cd | 1.2 | — | — | Si | 0.6 | O | 0.4 | N | 2.4 | Eu | 0.5 | 528 | 23 | 0.50 | 0.33 | 2.40 | 1.20 | 0.55 |
| 64 | Sr | 1.1 | Zn | 1.2 | — | — | Si | 0.6 | O | 0.4 | N | 2.4 | Eu | 0.5 | 530 | 24 | 0.50 | 0.33 | 2.40 | 1.20 | 0.55 |
| 65 | Sr | 1.1 | Cd | 1.2 | — | — | Si | 0.6 | O | 0.4 | P | 2.4 | Eu | 0.5 | 529 | 24 | 0.50 | 0.33 | 2.40 | 1.20 | 0.55 |
| 66 | Sr | 1.1 | Cd | 1.2 | — | — | Si | 0.6 | O | 0.4 | As | 2.4 | Eu | 0.5 | 529 | 22 | 0.50 | 0.33 | 2.40 | 1.20 | 0.55 |
| 67 | Sr | 1.1 | Cd | 1.2 | — | — | Si | 0.6 | O | 0.4 | Sb | 2.4 | Eu | 0.5 | 528 | 21 | 0.50 | 0.33 | 2.40 | 1.20 | 0.55 |
| 68 | Sr | 1.1 | Cd | 1.2 | — | — | Si | 0.6 | O | 0.4 | Bi | 2.4 | Eu | 0.5 | 528 | 23 | 0.50 | 0.33 | 2.40 | 1.20 | 0.55 |
| 69 | Sr | 1.1 | Cd | 1.2 | — | — | Si | 0.6 | O | 0.4 | N | 2.4 | Sm | 0.5 | 527 | 23 | 0.50 | 0.33 | 2.40 | 1.20 | 0.55 |
| 70 | Sr | 1.1 | Cd | 1.2 | — | — | Si | 0.6 | O | 0.4 | N | 2.4 | Yb | 0.5 | 527 | 22 | 0.50 | 0.33 | 2.40 | 1.20 | 0.55 |

Where, “—” in Table 1 represents that it does not exist substantially.

For the convenience of explanation, the preparation methods of the light-conversion materials are described in detail below with Examples 43, 45 and 46.

### <Example 43> Sr_{1.1}Cd_{1.2}Si_{0.6}O_{0.4}N_{2.4}:Eu_{0.5}

About 0.02 moles of fusing agent (e.g., NaF, Na₂CO₃), about 1.1 moles of SrCO₃, about 1.2 moles of CdO, about 0.6 moles of SiO₂, and about 2.4 moles of sodium nitrate are dissolved in dilute nitric acid solution to obtain the first mixture. Next, the first mixture is placed in a ceramic vessel and sintered at 600° C. for about 144 hours, then cooled down to room temperature (20° C.), taken out and ground to obtain the first product. 0.25 mol of Eu₂O₃ is added to the first product to obtain a second mixture, and the second mixture is calcined at 1200° C. for at least 24 hours in an atmosphere of 5% hydrogen (and 95% nitrogen). After the calcination process is finished, the second mixture is cooled down to room temperature and taken out. Next, it is washed twice with EtOH solution, washed twice with n-hexane, and then dried to obtain the light-conversion material Sr_{1.1}Cd_{1.2}Si_{0.6}O_{0.4}N_{2.4}:Eu_{0.5}.

### <Example 45> Sr_{0.5}Cd₄Al_{0.5}Si_{0.1}O_{0.1}N_{3.9}:Eu_{0.5}

About 0.02 moles of fusing agent (e.g., NaF, Na₂CO₃), about 0.5 moles of SrCO₃, about 4 moles of CdO, about 0.25 moles of Al₂O₃, about 0.1 moles of SiO₂, and about 3.9 moles of sodium nitrate are dissolved in dilute nitric acid solution to obtain the first mixture. Next, the first mixture is placed in a ceramic vessel and sintered at 600° C. for about 144 hours, then cooled down to room temperature (20° C.), taken out and ground to obtain the first product. 0.25 mol of Eu₂O₃ is added to the first product to obtain a second mixture, and the second mixture is calcined at 1200° C. for at least 24 hours in an atmosphere of 5% hydrogen (and 95% nitrogen). After the calcination process is finished, the second mixture is cooled down to room temperature and taken out. It is washed twice with EtOH solution, washed twice with n-hexane, and then dried to obtain the light-conversion material Sr_{0.5}Cd₄Al_{0.5}Si_{0.1}O_{0.1}N_{3.9}:Eu_{0.5}.

### <Example 46> Sr₂Cd_{2.7}Al_{0.6}Si_{0.1}O_{0.1}N₄:Eu_{0.3}

About 0.02 moles of fusing agent (e.g., NaF, Na₂CO₃), about 2 moles of SrCO₃, about 2.7 moles of CdO, about 0.3 moles of Al₂O₃, about 0.1 moles of SiO₂, and about 4 moles of sodium nitrate are dissolved in dilute nitric acid solution to obtain the first mixture. Next, the first mixture is placed in a ceramic vessel and sintered at 600° C. for about 144 hours, then cooled down to room temperature (20° C.), taken out and ground to obtain the first product. 0.15 mol of Eu₂O₃ is added to the first product to obtain a second mixture, and the second mixture is calcined at 1200° C. for at least 24 hours in an atmosphere of 5% hydrogen (and 95% nitrogen). After the calcination process is finished, the second mixture is cooled down to room temperature and taken out. It is washed twice with EtOH solution, washed twice with n-hexane, and then dried to obtain the light-conversion material Sr₂Cd_{2.7}Al_{0.6}Si_{0.1}O_{0.1}N₄:Eu_{0.3}.

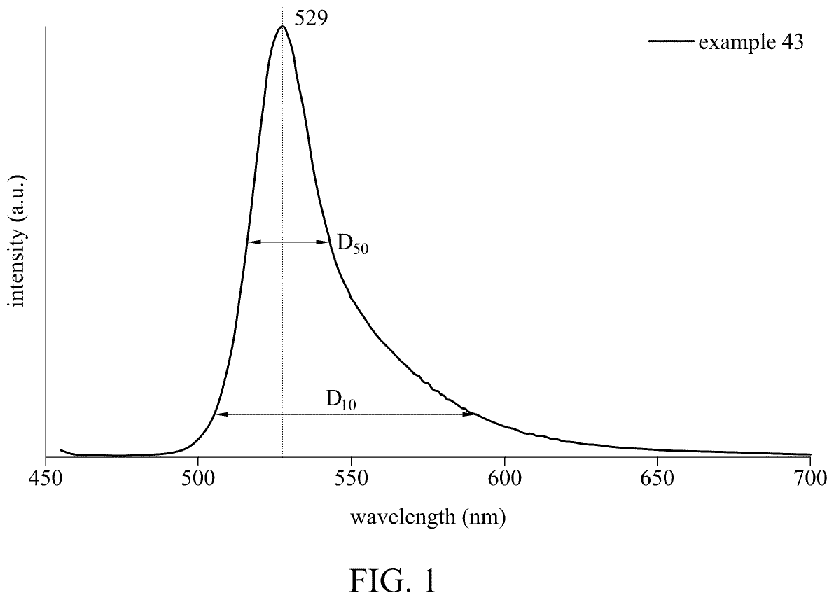

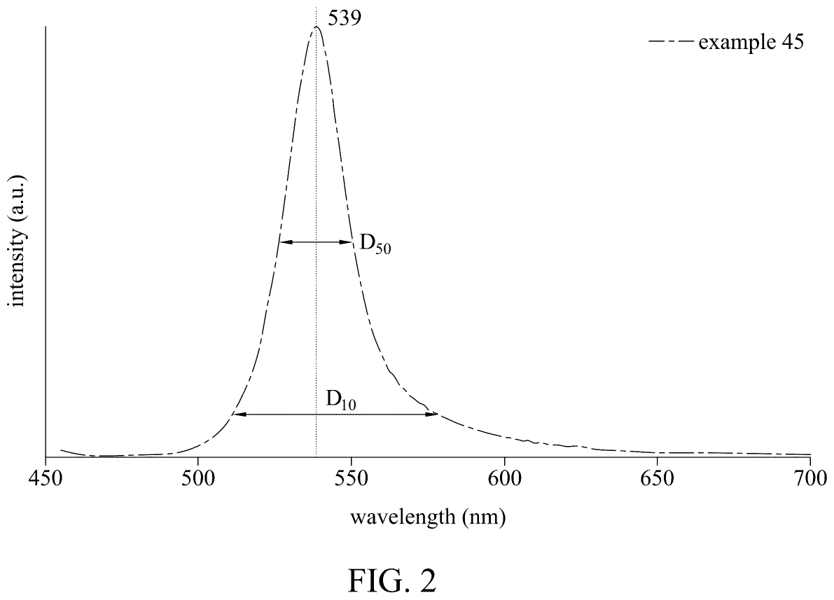

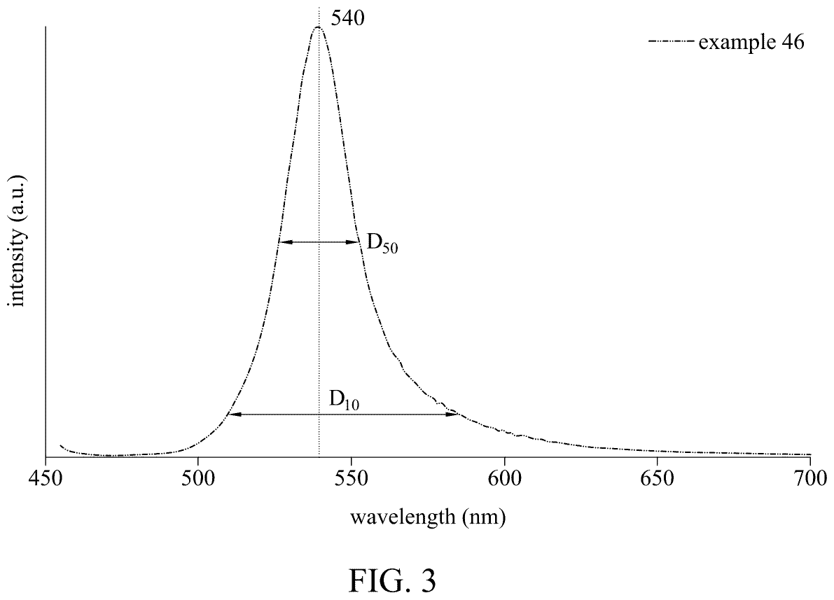

In some embodiments, the emission spectrum of the light-conversion material is measured by a fluorescence spectrometer (manufacturer: HORIBA, model: FluoroMax PLUS), and the results are listed in Table 1 and FIGS. 1 to 4. In some embodiments, the emission spectrum of the light-conversion material is measured at the excitation light with the peak emission wavelength in a range above 400 nm and below 480 nm. Specifically, the emission spectrum is measured by filling the solid powder of the light-conversion material into the carrier of the fluorescence spectrometer, and measuring the spectrum under the excitation light of 450 nm.

As shown in table 1, in some embodiments (e.g. Examples 1 to 3), as the content of M is increased, the peak value is increased, and the peak wavelength shifts towards a longer wavelength. As shown in Table 1, in some embodiments (e.g. Examples 3 to 6), as the content of D is increased, the FWHM is narrower. Wherein, compared with Examples 3 to 5, Example 6 has the most D content and the least C content, so the FWHM of Example 6 is the smallest. In some embodiments (e.g. Example 5 and Examples 7 to 9), as the content of A is decreased, the peak value is decreased, and the peak wavelength shifts towards a shorter wavelength. In some embodiments (e.g. Example 5 and Examples 10 to 12), as the content of C is increased, the FWHM is increased. In some embodiments (e.g. Example 10 and Examples 13 to 15), as the content of C is decreased, the FWHM is decreased. As the content of E is increased, the peak value is increased, and the wavelength shifts towards a longer wavelength.

In some embodiments (e.g. Examples 1, 16, and 17, or Examples 7, 29, and 30), the peak value increases while the FWHM remains unchanged after replacing Sr with Ca or Ba. Since the properties of the same group elements are similar but the atomic radii are different, when the same group elements are used to replace Sr, the peak value of the green light emitted by the light-conversion material can be changed without significantly affecting the FWHM. In some embodiments (e.g. Examples 1 and 18, or Examples 7 and 31), the peak value and FWHM remain unchanged after replacing Cd with Zn, since the lattice arrangements of Cd and Zn are similar and Cd and Zn are elements in the same group. In some examples (for example, Examples 8, 19, and 20), the peak value and FWHM remain unchanged after replacing Al with B or Ga. In some examples (e.g. Examples 1, 21, and 22, or Examples 7, 32, and 33), the peak value and FWHM remain unchanged after replacing O with S or Se. In some embodiments (e.g. Examples 14, and 23 to 26, or Examples 7 and 33 to 37), the peak value and FWHM remain unchanged after replacing N with P, As, Sb, or Bi. In some examples (e.g. Examples 1, 27, and 28, or Examples 7, 38, and 39), the peak value and FWHM remain unchanged after replacing Eu with Sm or Yb.

As shown in Table 1, in some embodiments, the ratio of c to n may be less than 3 (c/d<3), so that the FWHM (or D₅₀) is less than or equal to 33 nm (FWHM≤33 nm). In some embodiments, the ratio of c to d may be less than 1 (c/d<1), such that the FWHM (or D₅₀) is less than or equal to 27 nm (FWHM≤27 nm). In some embodiments, the ratio of c to d may be less than 0.5 (c/d<0.5), such that the FWHM (or D₅₀) is less than or equal to 25 nm (FWHM≤25 nm). Accordingly, the C content may be decreased while the D content is fixed, or the D content may be increased while the C content is fixed, so as to further reduce the FWHM of the light-conversion material. For example, FWHM may be reduced by reducing the content of silicon (Si).

As shown in Table 1, in some embodiments, the ratio of e to n may be less than 2 (e/d<2), so that the FWHM (or D₅₀) is less than or equal to 33 nm (FWHM≤33 nm). In some embodiments, the ratio of e to d may be less than 1.5 (e/d<1.5), such that the FWHM (or D₅₀) is less than or equal to 27 nm (FWHM≤27 nm). In some embodiments, the ratio of e to d may be less than 0.83 (e/d<0.83), such that the FWHM (or D₅₀) is less than or equal to 25 nm (FWHM≤25 nm). Accordingly, the content of E may be decreased while the content of D is fixed, or the content of D may be increased while the content of E is fixed, so as to further reduce the FWHM of the light-conversion material. For example, the content of sulfur (S) may be reduced to reduce FWHM.

As shown in Table 1, in some embodiments, the ratio of n to r may be greater than 2 (d/r>2), so that the FWHM (or D₅₀) is less than or equal to 33 nm (FWHM≤33 nm). In some embodiments, the ratio of d to r may be greater than 4.8 (d/r>4.8), such that the FWHM (or D₅₀) is less than or equal to 25 nm (FWHM≤25 nm). In some embodiments, the ratio of d to r may be greater than 9 (d/r>9), such that the FWHM (or D₅₀) is less than or equal to 24 nm (FWHM≤24 nm). Accordingly, the content of D may be increased while the content of R is fixed, or the content of R may be decreased while the content of D is fixed, so as to further reduce the FWHM of the light-conversion material. For example, FWHM may be reduced by reducing the content of cadmium (Cd).

As shown in Table 1, in some embodiments, the ratio of c to r may be less than 6 (c/r<6), so that the FWHM (or D₅₀) is less than or equal to 33 nm (FWHM≤33 nm). In some embodiments, the ratio of c to r may be less than 5 (c/r<5), such that the FWHM (or D₅₀) is less than or equal to 27 nm (FWHM≤27 nm). In some embodiments, the ratio of c to r may be less than 1.2 (c/r<1.2), such that the FWHM (or D₅₀) is less than or equal to 25 nm (FWHM≤25 nm). Accordingly, the content of C may be reduced while the content of R is fixed, or the content of R may be increased while the content of C is fixed, so as to further reduce the FWHM of the light-conversion material. For example, FWHM may be reduced by reducing the content of silicon (Si).

As shown in Table 1, in some embodiments, the ratio of c to m may be less than 6 (c/m<6), so that the FWHM (or D₅₀) is less than or equal to 33 nm (FWHM≤33 nm). In some embodiments, the ratio of c to m may be less than 5 (c/m<5), such that the FWHM (or D₅₀) is less than or equal to 27 nm (FWHM≤27 nm). In some embodiments, the ratio of c to m may be less than 0.55 (c/m<0.55), such that the FWHM (or D₅₀) is less than or equal to 25 nm (FWHM≤25 nm). Accordingly, the content of C may be reduced while the content of M is fixed, or the content of M may be increased while the content of C is fixed, so as to further reduce the FWHM of the light-conversion material. For example, FWHM may be reduced by reducing the content of silicon (Si).

FIGS. 1 to 3 are emission spectrums of the wavelength and intensity of light-conversion materials according to Examples 43, 45 and 46 of the present disclosure, respectively, and the values of the emission spectrums are listed in Table 2.

TABLE 2

| | 50% of the maximum emission intensity | | | 10% of the maximum emission intensity | | |
|---|---|---|---|---|---|---|
| | maximum value | minimum value | | maximum value | minimum value | |
| | of emission | of emission | | of emission | of emission | |
| Ex. | wavelength | wavelength | D₅₀ | wavelength | wavelength | D₁₀ |
| 43 | 541 | 518 | 23 | 588 | 497 | 91 |
| 45 | 550 | 528 | 22 | 589 | 502 | 87 |
| 46 | 552 | 527 | 25 | 590 | 500 | 90 |

As shown in Table 2, the respective FWHMs of Example 43, Example 45, and Example 46 are 23 nm, 22 nm and 25 nm and satisfy the condition of 2.5D₅₀≤D₁₀≤5.5D₅₀. Therefore, the light-conversion material of the present disclosure has a narrow FWHM, a narrow wave width, high color accuracy, and/or high light-conversion efficiency.

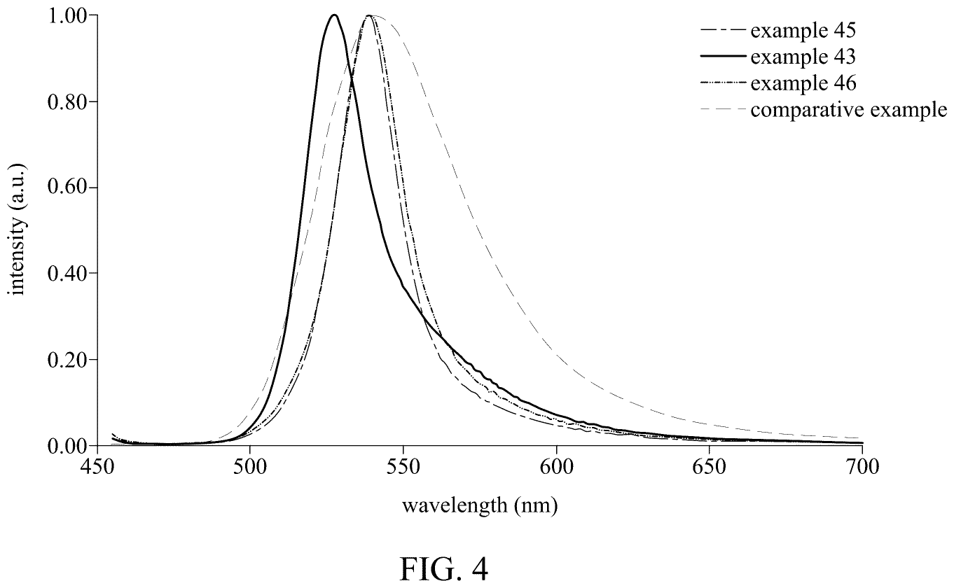

Referring to FIG. 4, it is a emission spectrum of a wavelength and an intensity of light-conversion materials according to Example 43, Example 45, Example 46 and a comparative example of the present disclosure. Wherein, the comparative example is sialon (β-SiAlON) phosphor. As shown in FIG. 4, the light-conversion material of the present disclosure has a narrower FWHM and a narrower wave width than that of β-SiAlON phosphor (FWHM of β-SiAlON phosphor is about 50 nm).

It should be noted that the green light-conversion material disclosed in the present disclosure is a narrow-spectrum light-conversion material applicable to the backlight of the display, and has spectral tunability, which can improve the problem of low color purity of traditional green light-conversion materials. The light-conversion material applied in the backlight of the display enables the display to have a wide color gamut (WCG). Furthermore, when the color light with a narrow light emission spectrum is filtered by the color filter in the display, it suffers less loss.

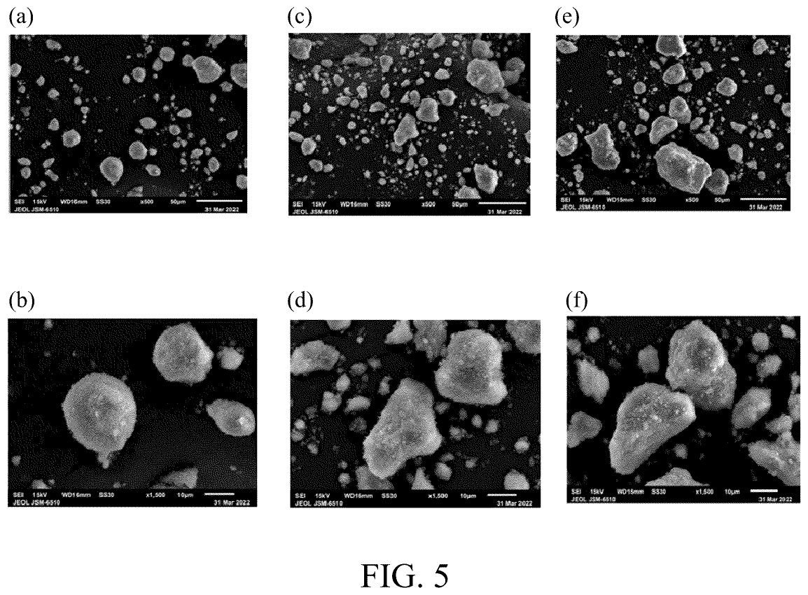

Referring to FIG. 5, it is a scanning electron microscope (SEM) image of a light-conversion material according to some embodiments of the present disclosure. Wherein, portion (a) and portion (b) of FIG. 5 are the SEM images of Example 43 under different sizes, respectively. Portion (c) and portion (d) of FIG. 5 are the SEM images of Example 45 under different sizes, respectively. Portion (e) and portion (f) of FIG. 5 are the SEM images of Example 46 under different sizes, respectively. As shown in FIG. 5, the light-conversion material of the present disclosure has a complete structure and uniform size. Furthermore, the size of the light-conversion material may be less than or equal to 40 m, thereby improving the applicability of the light-conversion material. For example, the light-conversion material of the present disclosure may be applied to mini light-emitting diodes (mini LEDs).

In some embodiments, the present disclosure further provides a light-emitting device including a light source and a wavelength conversion portion, wherein the wavelength conversion portion includes the green light-conversion material of the present disclosure represented by formula (1) as described above. In some embodiments, according to the light color required by the light-emitting device, the wavelength conversion portion may further include other light-conversion materials combined with the green light-conversion material of the present disclosure, so that the light-emitting device may be used in various fields, such as lighting, the backlight unit of the display, the central control panel and instrument panel of the vehicle, and the like.

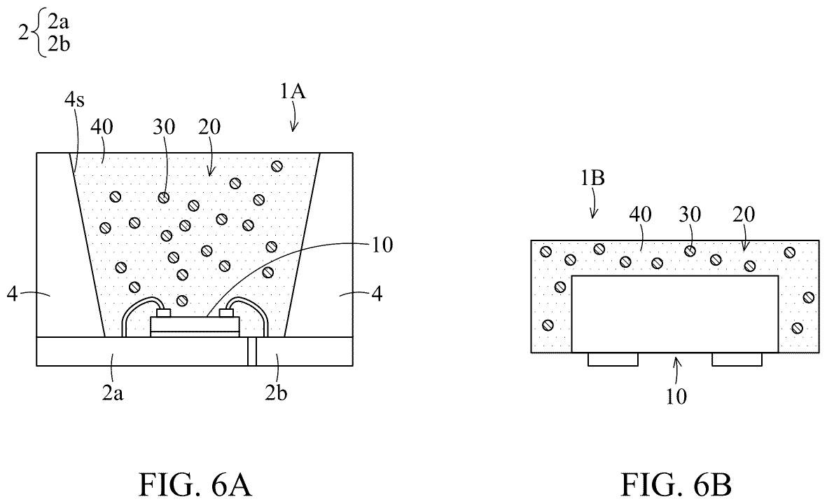

Referring to FIGS. 6A and 6B, they are respective schematic diagrams of light-emitting devices 1A and 1B according to some embodiments of the present disclosure. As shown in FIG. 6A, the light-emitting device 1A may be an LED lighting device. The light-emitting device 1A may include a lead frame 2, walls 4, a light source 10, and a first wavelength conversion portion 20. The lead frame 2 includes a first lead portion 2a and a second lead portion 2b. The walls 4 are located on the lead frame 2 and forms an accommodation space 4s. The light source 10 is used to emit an excitation light with an emission peak wavelength in the range above 400 nm and below 480 nm. In some embodiments, the light source 10 may be a blue LED chip or a UV LED chip located on the lead frame 2 in the accommodation space 4s and surrounded by the walls 4. The LED chip (light source 10) may be a horizontal, vertical, or flip-chip chip, and FIG. 6A is an example of a horizontal LED chip for illustration. As shown in FIG. 6A, the positive and negative electrodes of the LED chip (light source 10) may be electrically connected to the first lead portion 2a and the second lead portion 2b by wire bonding. The first wavelength conversion portion 20 is located in the accommodation space 4s and covers the LED chip (light source 10), wherein the first wavelength conversion portion 20 may include a first light-conversion material 30 represented by the aforementioned formula (1) and a first matrix 40, and the first light-conversion material 30 may be uniformly dispersed in the first matrix 40. The first light-conversion material 30 of the present disclosure absorbs the excitation light emitted by the blue or UV LED chip (the light source 10), and converts the absorbed excitation light into green light with a narrow FWHM. The green light has an emission peak wavelength above 480 nm and below 580 nm, and the green light has a maximum emission intensity. When the emission intensity is 50% of the maximum emission intensity, the difference between the maximum value and the minimum value of the emission wavelength of the light-conversion material is D₅₀. When the emission intensity is 10% of the maximum emission intensity, the difference between the maximum value and the minimum value of the emission wavelength of the light-conversion material is D₁₀, and 2.5 D₅₀≤D₁₀≤5.5 D₅₀. In some embodiments, the LED chip may use a chip with a smaller size, such as a mini light-emitting diode (mini LED) chip or a micro light-emitting diode (micro LED) chip.

In some embodiments, the first matrix 40 may include a transparent resin. For example, the first matrix 40 may be acrylate resin, organosiloxane resin, acrylate-modified polyurethane, acrylate-modified silicone resin, or epoxy resin. In some embodiments, the first wavelength conversion portion 20 may further include diffusion particles uniformly dispersed in the first matrix 40. The diffusion particles may scatter the light incident into the first matrix 40. The diffusion particles may include inorganic particles, organic polymer particles, or combinations thereof. Examples of inorganic particles include silicon oxide, titanium oxide, aluminum oxide, calcium carbonate, barium sulfate, or any combination thereof, but the present disclosure is not limited thereto. Examples of organic polymer particles include polymethyl methacrylate (PMMA), polystyrene (PS), acrylonitrile-butadiene-styrene copolymer (ABS), polyurethane (PU), or any combination thereof, but the present disclosure is not limited thereto.

As shown in FIG. 6B, the light-emitting device 1B may be a chip-scale package (CSP), wherein the light source 10 may be a flip-chip blue LED chip or UV LED chip. The first wavelength conversion portion 20 includes the first light-conversion material 30 represented by the aforementioned formula (1) that absorbs blue light or UV light and converts it into green light with a narrow FWHM. As shown in FIG. 6B, the first wavelength conversion portion 20 is conformed to the shape of the LED chip and formed on the surface of the LED chip (light source 10) to cover top and side surfaces of the LED chip. In other embodiments, the first wavelength conversion portion 20 may cover the top surface of the LED chip (light source 10). In some embodiments, the light-emitting diode chip includes a mini LED chip and a micro LED chip.

In some embodiments, the LED light-emitting device including the green light-conversion material of the present disclosure, such as the aforementioned light-emitting device 1A and CSP light-emitting device 1B which emit the green light, may be used as green sub-pixel in a LED display or a micro LED display.

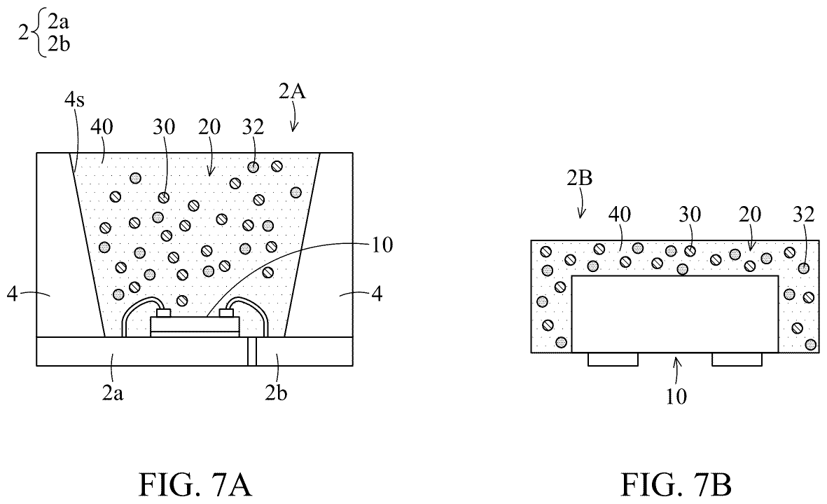

Referring to FIG. 7A and FIG. 7B, they are schematic diagrams of light-emitting devices 2A and 2B according to some embodiments of the present disclosure, respectively. As shown in FIG. 7A, the first wavelength conversion portion 20 in the light-emitting device 2A may further include a second light-conversion material 32. In some embodiments, the second light-conversion material 32 is different from the first light-conversion material 30 including a green light-conversion material represented by the aforementioned formula (1) of the present disclosure. In some embodiments, the second light-conversion material 32 and the first light-conversion material 30 are dispersed in the first matrix 40. In one embodiment in which a light-emitting device 2A emits white light, the light source 10 may be a blue light-emitting diode chip for emitting blue light, and the second light-conversion material 32 includes a red light-conversion material and is mixed with the first light-conversion material 30, which is green, of the present disclosure, wherein the red light-conversion material 32 and the first light-conversion material 30 absorb portions of the blue light to emit red light and green light, respectively. Then, the red light and the green light are mixed with another portion of the blue light to form the white light. In another embodiment which the light-emitting device 2A emits white light, the light source 10 is a UV light-emitting diode chip, the second light-conversion material 32 includes a blue light-conversion material and a red light-conversion material and is mixed with the first light-conversion material 30 of the present disclosure, wherein the blue light-conversion material, the red light-conversion material, and the green light-conversion material absorb portions of the ultraviolet light to emit blue light, red light, and green light respectively. Then the blue light, the red light, and the green light are mixed to form the white light. In addition, the red light-conversion material may be red quantum dots, or red phosphors, such as (Sr,Ca)AlSiN₃:Eu²⁺, Ca₂Si₅N₈:Eu²⁺, Sr(LiAl₃N₄):Eu²⁺, manganese-doped red fluoride phosphors (for example, K₂GeF₆:Mn⁴⁺, K₂SiF₆:Mn⁴⁺, K₂TiF₆:Mn⁴⁺), but the present disclosure is not limited thereto. The blue light-conversion material may be blue quantum dots or blue phosphor, but the present disclosure is not limited thereto. In some embodiments, the light-conversion material 32 may include other kinds of green light-conversion materials, such as green quantum dots, aluminum garnet (LuAG) phosphor, yttrium aluminum garnet (YAG) phosphor, sialon (β-SiAlON) phosphor, silicate phosphor, but the present disclosure is not limited thereto. Similarly, as shown in FIG. 7B, in the CSP light-emitting device 2B, the wavelength conversion portion 20 may further include other light-conversion materials 32 mixed with the first light-conversion material 30, which is green, of the present disclosure.

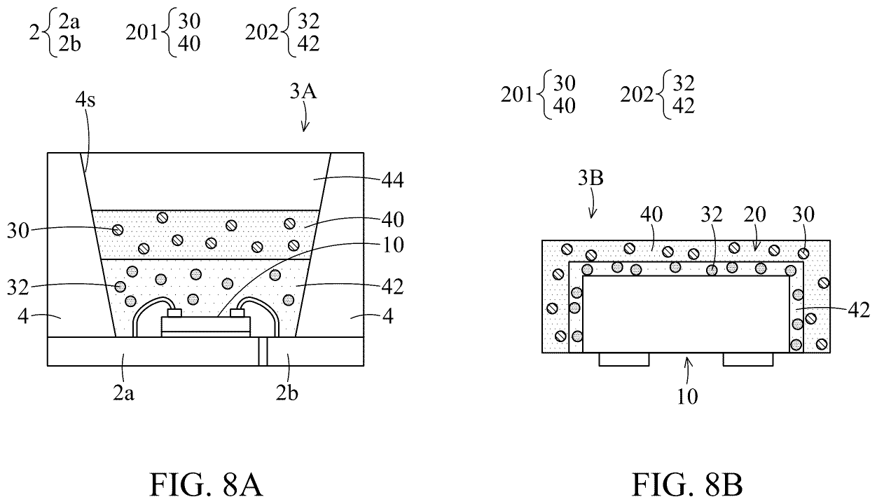

Referring to FIGS. 8A and 8B, they are schematic diagrams of light-emitting devices 3A and 3B according to some embodiments of the present disclosure, respectively. As shown in FIG. 8A, the light-emitting device 3A may include a first wavelength conversion portion 201 and a second wavelength conversion portion 202, wherein the second wavelength conversion portion 202 is located on the lead frame 2 and covers the LED chip (light source 10), and the first wavelength conversion portion 201 is located on the second wavelength conversion portion 202. The first wavelength conversion portion 201 includes a first light-conversion material 30 and the first matrix 40, and the light-conversion material 30 is a green light-conversion material represented by the aforementioned formula (1) and dispersed in the first matrix 40. The second wavelength conversion portion 202 includes a second light-conversion material 32 and a second matrix 42, and the second light-conversion material 32 is dispersed in the second matrix 42. In some embodiments, the second light-conversion material 32 is different than green light-conversion material 30 of the present disclosure. Taking the white light-emitting device 3A as an example, the LED chip (light source 10) emits blue light, the light-conversion material 32 may be a red light-conversion material. The light-conversion material 32 absorbs a portion of the blue light and emits red light, and the green light-conversion material 30 of the present disclosure absorbs a portion of the blue light and emit green light. In some embodiments, the first matrix 40 and the second matrix 42 may include transparent resins, such as acrylic resins, organosiloxane resins, acrylate-modified polyurethanes, acrylate-modified silicone resins, or epoxy resins. In some embodiments, the materials of the first matrix 40 and the second matrix 42 may be the same or different. In some embodiments, a protection layer 44 may be formed on the wavelength conversion portion 201. The protection layer 44 may include transparent resin, such as acrylic resin, organosiloxane resin, acrylate-modified polyurethane, acrylate-modified silicone resin, or epoxy resin. Similarly, as shown in FIG. 8B, in the CSP light-emitting device 3B, a first wavelength conversion portion 201 and a second wavelength conversion portion 202 is located on the light-emitting diode chip 10, wherein the second wavelength conversion portion 202 conforms to the shape of the light-emitting diode 10 and covers the top surface and side surfaces of the light-emitting diode 10. Also, the first wavelength conversion portion 201 covers the top surface and side surfaces of the second wavelength conversion portion 202. Taking the white light-emitting device 3B as an example, the flip-chip LED chip (light source 10) emits blue light, the second light-conversion material 32 may be a red light-conversion material. The second light-conversion material 32 absorbs a portion of the blue light and emits the red light, and the green light-conversion material 30 of the present disclosure absorbs a portion of the blue light and emits the green light.

In some embodiments, the present disclosure provides a display device, and the display device includes a backlight unit emitting white light. The backlight unit may include a plurality of white light-emitting devices as shown in FIG. 7A, FIG. 7B, FIG. 8A, and/or FIG. 8B. In some embodiments, the display device may be a liquid crystal display. Since the green light-conversion material MₘD_{d}AₐC_{c}EₑG_{g}:Rᵣ of the present disclosure has a narrow FWHM, it can be combined with a red wavelength conversion material (such as red phosphor K₂SiF₆:Mn⁴⁺) with a narrow emission spectrum to make the display have a wide color gamut.

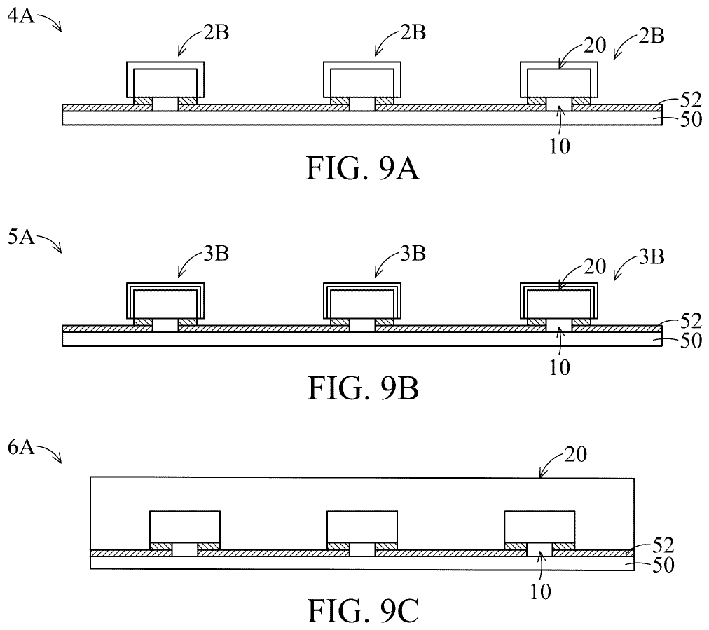

Referring to FIG. 9A, it is a schematic diagram of a backlight device 4A according to some embodiments of the present disclosure. In some embodiments, the backlight device 4A may include a plurality of light-emitting devices 2B emitting white light as shown in FIG. 7B. In some embodiments, the backlight device 4A may further include a plurality of white light-emitting devices 2B, a substrate 50, and a conductive layer 52. In some embodiments, the conductive layer 52 may be disposed on the substrate 50. In some embodiments, the white light-emitting device 2B includes a light-emitting diode chip (light source 10) and a wavelength conversion portion 20. Wherein the light-emitting diode chip (light source 10) is flip-chip disposed on the substrate 50 and electrically connected to the conductive layer 52. The substrate 50 may be a transparent substrate or an opaque substrate. In some embodiments, the substrate 50 may be a flexible substrate. In other embodiments, the substrate 50 may be a rigid substrate, such as a sapphire substrate, a silicon substrate, a glass substrate, a printed circuit board, a metal substrate, a ceramic substrate, but the present disclosure is not limited thereto.

Referring to FIG. 9B, it is a schematic diagram of a backlight device 5A according to some embodiments of the present disclosure. In some embodiments, the backlight device 5A may include a plurality of light-emitting devices 3B emitting white light as shown in FIG. 8B.

Referring to FIG. 9C, it is a schematic diagram of a backlight device 6A according to some embodiments of the present disclosure. In some embodiments, the backlight device 6A includes a plurality of light sources 10, a substrate 50, a conductive layer 52, and a wavelength conversion portion 20. The light source 10 is a blue LED chip or UV LED chip, and the wavelength conversion portion 20 is located on the surface of the substrate 50 and covers the light source 10. When the light source 10 is a blue LED chip, the wavelength conversion portion 20 includes a red light-conversion material mixed with the green light-conversion material represented by the aforementioned formula (1). When the light source 10 is a UV LED chip, the wavelength conversion portion 20 includes a mixture of blue light-conversion material, red light-conversion material, and the green light-conversion material represented by formula (1).

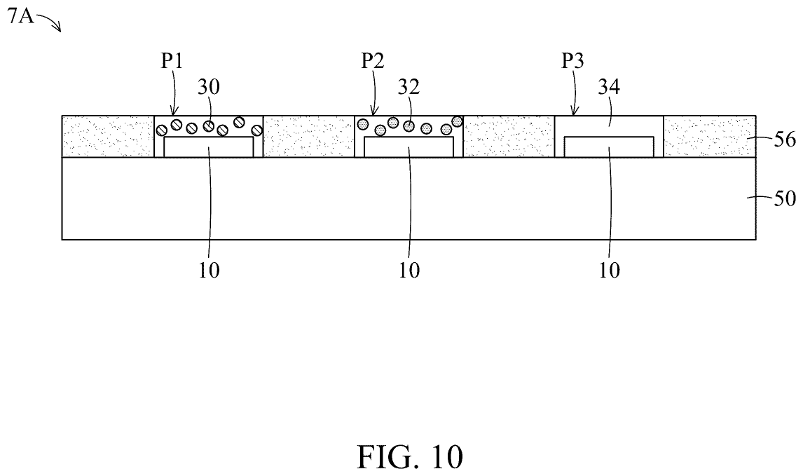

In some embodiments, the LED light-emitting device including the green light-conversion material of the present disclosure may be used as a green sub-pixel in an LED display or a micro LED display. FIG. 10 is a schematic diagram of an LED display device 7A according to some embodiments of the present disclosure. In some embodiments, the LED display device 7A may include a substrate 50, sub-pixels P1 to P3, and a light-shielding layer 56 disposed between adjacent sub-pixels P1 to P3. In some embodiments, the light source 10 is a blue light-emitting diode chip. In some embodiments, the sub-pixel P1 may be a sub-pixel emitting green light, and the first light-conversion material 30 may include the light-conversion material represented by the aforementioned formula (1). In some embodiments, sub-pixel P2 may be a sub-pixel emitting red light, and the second light-conversion material 32 may include a red light-conversion material. In some embodiments, the sub-pixel P3 may be a sub-pixel emitting blue light, and the cover layer 34 may include an optically transparent material. In some embodiments, the light-shielding layer 56 may include a material that blocks light from passing through, such as a black photoresist material.

Accordingly, some embodiments of the present disclosure provide light-conversion materials with narrow FWHM, narrow wave width, high color accuracy, high light-conversion efficiency, and/or high gamut coverage (color coverage) and are suitable to be applied in the WCG applications, as well as a light-emitting device and a display device including the same.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of the present disclosure, and that they can make various changes, substitutions, and replacements without violating the spirit and scope of the present disclosure. Therefore, the scope of protection of the present disclosure is defined by the scope of the claim. In addition, embodiments of the present disclosure are not intended to limit the present disclosure.

Terms such as “features”, “benefits”, and the like introduced throughout the specification are not all features and benefits that can be achieved by using the present disclosure and should/could not be achieved in any single embodiment of the present disclosure. In contrast, the terms relating to features and benefits are understood to mean that the particular features, benefits, or characteristics described in conjunction with the embodiments are included in at least one embodiment of the present disclosure. Thus, the discussion of the terms “features”, “benefits”, and the like throughout the specification may, but does not necessarily, represent the same embodiment.

Furthermore, the features, benefits, and characteristics described in the present disclosure may be combined in any suitable manner in one or more embodiments. According to the description herein, those having ordinary knowledge in the art to which the present disclosure belongs will realize that the present disclosure can be implemented without one or more of particular features or benefits of a particular embodiment. In other instances, additional features and benefits may be shown in some embodiments while they may not be shown in all embodiments of the present disclosure.

1. A light-conversion material, represented by formula (I):
MmDdAaCcEeGg:Rr (I),
wherein:
M is Ca, Sr, or Ba;
D is Zn, Cd, or a combination thereof,
A is B, Al, or Ga;
C is Si;
E is O, S, or Se;
G is N, P, As, Sb, or Bi;
R is Eu, Sm, or Yb;
0.5<m<2;
1<d<4;
0<a<2;
0.1<c<3.5;
0.1<e<4;
0.5<g<5.5; and
0.1<r<1.

2. The light-conversion material as claimed in claim 1, wherein c/d<3.

3. The light-conversion material as claimed in claim 2, wherein c/d<1.

4. The light-conversion material as claimed in claim 3, wherein c/d<0.5.

5. The light-conversion material as claimed in claim 1, wherein e/d<2.

6. The light-conversion material as claimed in claim 5, wherein e/d<1.5.

7. The light-conversion material as claimed in claim 6, wherein e/d<0.83.

8. The light-conversion material as claimed in claim 1, wherein d/r>2.

9. The light-conversion material as claimed in claim 8, wherein d/r>4.8.

10. The light-conversion material as claimed in claim 9, wherein d/r>9.

11. The light-conversion material as claimed in claim 1, wherein c/r<6.

12. The light-conversion material as claimed in claim 11, wherein c/r<1.2.

13. The light-conversion material as claimed in claim 1, wherein c/m<6.

14. The light-conversion material as claimed in claim 13, wherein c/m<0.55.

15. The light-conversion material as claimed in claim 1, wherein the light-conversion material absorbs a light in a wavelength range above 400 nm and below 480 nm to emit a green light, the green light has an emission peak wavelength in a range above 480 nm and below 580 nm, and the green light has a maximum emission intensity, wherein:
when an emission intensity is 50% of the maximum emission intensity, a difference between a maximum value and a minimum value of an emission wavelength of the light-conversion material is D50,
when an emission intensity is 10% of the maximum emission intensity, a difference between a maximum value and a minimum value of the emission wavelength of the light-conversion material is D10, and 2.5 D50<D10<5.5 D50.

16. A light-emitting device, comprising:
a light source emitting an excitation light, wherein the excitation light has an emission peak wavelength in a range above 400 nm and below 480 nm; and
a light-conversion material as claimed in claim 1, wherein the light-conversion material absorbs a portion of the excitation light to emit a green light, the green light has an emission peak wavelength in a range above 480 nm and below 580 nm, and the green light has a maximum emission intensity, wherein:
when an emission intensity is 50% of the maximum emission intensity, a difference between a maximum value and a minimum value of an emission wavelength of the light-conversion material is D50,
when an emission intensity is 10% of the maximum emission intensity, a difference between a maximum value and a minimum value of the emission wavelength of the light-conversion material is D10, and 2.5 D50<D10<5.5 D50.

17. The light-emitting device as claimed in claim 16, further comprising a first wavelength conversion portion including the light-conversion material and a second wavelength conversion portion including another light-conversion material, wherein the second wavelength conversion portion covers the light source and the first wavelength conversion portion is on the second wavelength conversion portion.

18. The light-emitting device as claimed in claim 17, further comprising a protection layer on the first wavelength conversion portion.

19. A display device, comprising a light-emitting device as claimed in claim 16.

20. The display device as claimed in claim 19, further comprising another light-conversion material absorbs a portion of the excitation light to emit a red light.
